(19) United States
(12) Patent Application Publication
(10) Pub. No.: US 2012/0285532 A1
(43) Pub. Date: Nov. 15, 2012

(54) TRANSPARENT COLOR SOLAR CELLS

(75) Inventors: Sun Jin YUN, Daejeon (KR); JungWook LIM, Daejeon (KR); Yoo Jeong LEE, Seoul (KR)

(73) Assignee: ELECTRONICS AND TELECOMMUNICATIONS RESEARCH INSTITUTE, Daejeon (KR)

(21) Appl. No.: 13/470,255

(22) Filed: May 11, 2012

(30) Foreign Application Priority Data
May 12, 2011 (KR) 10-2011-0044789
Mar. 7, 2012 (KR) 10-2012-0023633

(51) Int. Cl. H01L 31/0248; H01L 31/0304; H01L 31/0296; H01L 31/0264; H01L 31/0272; B82Y 30/00

(52) U.S. Cl. 136/258; 136/252; 136/261; 136/265; 136/262; 136/260; 977/774; 977/948

(57) ABSTRACT

Provided is a transparent color solar cell, which includes a substrate, a first electrode layer disposed on the substrate, a transparent material layer including quantum dots having the same particle size, which absorb visible light provided from the sun through the first electrode layer and having a first wavelength region, and which selectively transmit visible light provided from the sun through the first electrode layer and having a second wavelength region, and a second electrode layer disposed on the transparent material layer.

### CROSS-REFERENCE TO RELATED APPLICATIONS

This U.S. non-provisional patent application claims priority under 35 U.S.C. § 119 of Korean Patent Application Nos. 10-2011-0044789, filed on May 12, 2011, and 10-2012-0023633, filed on Mar. 7, 2012, the entire contents of which are hereby incorporated by reference.

### BACKGROUND OF THE INVENTION

The present invention disclosed herein relates to a solar cell, and more particularly, to a transparent color solar cell capable of expressing various colors.

Solar cells are used as core parts in photovoltaic power generating apparatuses for converting solar radiation into electrical energy. Solar cells are used not only as power sources of portable electronic devices such as watches and calculators, but also in small-scale distributed generation devices installed on the roof of a building and the sunroof of a vehicle, and further, may be used in an industrial generating plant installed on a wide open terrain.

In general, a solar cell may be fabricated on a transparent substrate. When solar cells have an absorption rate smaller than 100% in visible light from the sun, they may be classified into transparent solar cells. This is because people can see an object or an external environment through transparent solar cells. Transparent solar cells may have a transmissivity of about 10% or larger in visible light. A transmitted amount of visible light may be determined according to an aperture ratio or thickness of a light absorption layer. A transmission wavelength of visible light may be determined according to a band gap of a light absorption layer.

With respect to source materials, crystalline solar cells include a single or poly crystalline opaque substrate having a certain thickness (normally 150 μm) or greater in order to form a PN junction device, and thus, are inappropriate to be used as transparent solar cells. However, thin film solar cells may include: a transparent substrate formed of glass, ceramic, or plastic; and a light absorption layer formed on the transparent substrate. When the light absorption layer transmits a certain amount of visible light, the thin film solar cell can function as a transparent solar cell. When a transparent solar cell is formed on an opaque substrate formed of steel or a certain type of plastic, the transparent solar cell can function as a color solar cell since light is reflected by the opaque substrate even though being not transmitted thereby. The transparent solar cells also show color of which intensity depends on the transparency of the solar cell.

There may be two methods of improving transmissivity of a light absorption layer. One is a method of adjusting an aperture ratio of the light absorption layer, which is most typical. In this case, a transparent solar cell has a transmission region separated from an absorption region of the light absorption layer. A photovoltaic power generating capacity may be reversely proportional to the transmissivity of the light absorption layer according to an area ratio of the transmission region to the absorption region. Thus, the photovoltaic power generating capacity of transparent solar cells having a transmission region may be decreased according to an increase of the transmissivity of a light absorption layer. The other one is a method of entirely absorbing and transmitting visible light through a light absorption layer, without discrimination between a transmission region and an absorption region. To this end, dye-sensitized solar cells are widely used. However, since dye-sensitized solar cells use a dye as a color filter to express a color, the photovoltaic power generating capacity thereof is low. In addition, since the lifetime of the dyes is short, the service life of the dye sensitized solar cell is also short.

### SUMMARY OF THE INVENTION

The present invention provides a transparent color solar cell, which can maximize photovoltaic efficiency and visual characteristics.

The present invention also provides a transparent color solar cell, which can express various colors.

Embodiments of the present invention provide transparent color solar cells including: a substrate; a first electrode layer disposed on the substrate; a transparent material layer including quantum dots having the same particle size, which absorb visible light provided from the sun through the first electrode layer and having a first wavelength, and which selectively transmit visible light provided from the sun through the first electrode layer and having a second wavelength; and a second electrode layer disposed on the transparent material layer.

In some embodiments, the quantum dots may include crystalline silicon.

In other embodiments, the quantum dots may include amorphous silicon.

In still other embodiments, the quantum dot including the crystalline silicon or the amorphous silicon may have a diameter ranging from about 1 nm to about 100 nm.

In another embodiments, the quantum dots may comprise at least one of silicon germanium (SiGe), copper indium disulfide (CuInS₂), copper indium gallium diselenide (CuInGaSe₂), cadmium telluride (CdTe), and gallium arsenide (GaAs).

In even other embodiments, the transparent material layer may include an inorganic dielectric.

In yet other embodiments, the inorganic dielectric may include at least one of a silicon oxide layer, a silicon nitride layer, and a silicon carbide layer.

In further embodiments, the inorganic dielectric may further includes at least one of an aluminum oxide layer, a titanium oxide layer, a vanadium oxide layer, a tantalum oxide layer, and a zirconium oxide layer.

In still further embodiments, the transparent color solar cell may further include: a first impurity-added layer disposed between the first electrode layer and the transparent material layer; and a second impurity-added layer disposed between the transparent material layer and the second electrode layer.

In still further embodiments, the first impurity-added layer may comprise p-type semiconductor layer; and wherein the second impurity-added layer may comprises n-type semiconductor layer.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIGS. 1 to 3 are cross-sectional views illustrating a transparent color solar cell according to an embodiment of the present invention; and

FIG. 4 is a graph illustrating visible light absorption wavelength range that is proportional to the size of first to third quantum dots of FIGS. 1 to 3.

### DETAILED DESCRIPTION OF PREFERRED EMBODIMENTS

Hereinafter, embodiments of the present invention will now be described in detail with reference to the accompanying drawings. The present invention and implementation methods thereof will be clarified through the following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art Like reference numerals refer to like elements throughout.

In the following description, the technical terms are used only for explaining exemplary embodiments while not limiting the present invention. The terms of a singular form may include plural forms unless referred to the contrary. The meaning of ‘comprises’ and/or ‘comprising’ specifies a property, a region, a fixed number, a step, a process, an element and/or a component but does not exclude other properties, regions, fixed numbers, steps, processes, elements and/or components. The meaning of ‘a wavelength’ specifies a wavelength region having an experimentally-inevitable broadness centered at a wavelength. Since exemplary embodiments are provided below, the order of the reference numerals given in the description is not limited thereto.

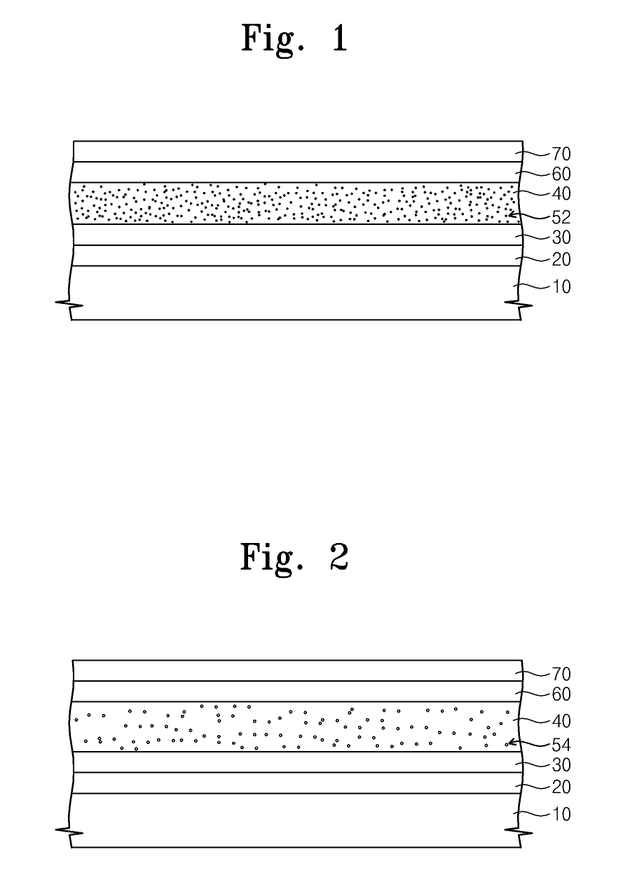

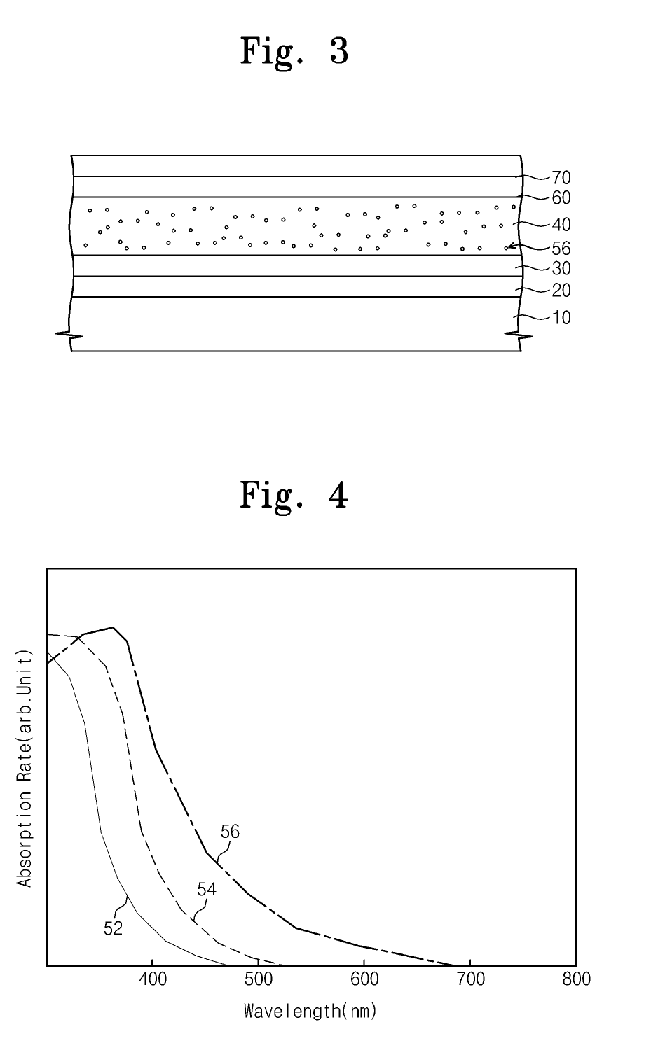

FIGS. 1 to 3 are cross-sectional views illustrating a transparent color solar cell according to an embodiment of the present invention. FIG. 4 is a graph illustrating visible light absorption wavelength range that is proportional to the size of first to third quantum dots 52, 54, and 56 of FIGS. 1 to 3. Distances between quantum dots of FIGS. 1 to 3 are exaggerated for clarity of illustration, and practical distances therebetween are determined to drive a solar cell. Particularly, practical distances between quantum dots may range from several A to several tens nm to drive a solar cell.

Referring to FIGS. 1 to 4, a transparent color solar cell according to the current embodiment may include the first to third quantum dots 52, 54, and 56, which have different particle sizes and absorb visible light of different wavelengths within a transparent material layer 40 between a first electrode layer 20 and a second electrode layer 70. The first to third quantum dots 52, 54, and 56 may absorb visible light of peak wavelength that increases in proportion to particle size, to generate electricity between the first electrode layer 20 and the second electrode layer 70. Also, the first to third quantum dots 52, 54, and 56 may transmit visible light of long wavelength that increases in proportion to particle size, and thus, may express different colors according to particle size.

Thus, the transparent color solar cell can maximize photovoltaic efficiency and visual characteristics. The first to third quantum dots 52, 54, and 56 are distinct from one another according to particle size. When the first, second, or third quantum dots 52, 54, or 56 have the same particle size, the first, second, or third quantum dots 52, 54, or 56 are similar or identical in transmission wavelength or absorption wavelength.

A substrate 10 may include a transparent substrate formed of glass, plastic, or ceramic. The first and second electrode layers 20 and 70 may include a transparent electrode such as indium tin oxide, F-doped tin oxide, or a zinc oxide layer doped with B, Ga, In, or Al. A first impurity-added layer 30 may include a p-type transparent semiconductor layer. A second impurity-added layer 60 may include an n-type transparent semiconductor layer.

The transparent material layer 40 may include an inorganic dielectric layer. For example, the transparent material layer 40 may include a silicon compound such as a silicon oxide layer, a silicon nitride layer, and a silicon carbide layer. In addition, the transparent material layer 40 may include at least one of an aluminum oxide layer, a titanium oxide layer, a vanadium oxide layer, a tantalum oxide layer, and a zirconium oxide layer. The first to third quantum dots 52, 54, and 56 may include at least one of silicon (Si), silicon germanium (SiGe), copper indium disulfide (CuInS₂), copper indium gallium diselenide (CuInGaSe₂), cadmium telluride (CdTe), and gallium arsenide (GaAs). For example, the first to third quantum dots 52, 54, and 56 may include amorphous silicon or crystalline silicon having an average diameter ranging from about 1 nm to about 100 nm. The first to third quantum dots 52, 54, and 56 may include silicon germanium having an average diameter ranging from about 1 nm to about 100 nm.

When an amount of the first to third quantum dots 52, 54, and 56 within the transparent material layer 40 is increased, transmissivity of the transparent material layer 40 may be decreased. Thus, the transmissivity of the transparent material layer 40 may depend on an amount of the first to third quantum dots 52, 54, and 56 therein.

The particle size of the first to third quantum dots 52, 54, and 56 may be determined according to a method of fabricating the transparent material layer 40. For example, source layers (not shown) stacked within the transparent material layer 40, and having a thickness of several nm or smaller may be thermally treated, and thus, be randomly aggregated to form the first, second, or third quantum dots 52, 54, or 56. The particle size of the first to third quantum dots 52, 54, and 56 may be proportional to the thickness of the source layers. As the thickness of the source layers within the transparent material layer 40 is increased, the particle size of the first to third quantum dots 52, 54, and 56 may be increased. For example, the transparent material layer 40 may have a first thickness d1, and include the first quantum dots 52. When the transparent material layer 40 has a second thickness d2 greater than the first thickness d1, the transparent material layer 40 may include the second quantum dots 54 that are greater in particle size than the first quantum dots 52. Transparency of the transparent color solar cell may depend on the thickness of the transparent material layer 40 including the first, second, or third quantum dots 52, 54, or 56. Particularly, as the thickness of the transparent material layer 40 is decreased, the transparency may be increased.

That is, the average diameter of the first to third quantum dots 52, 54, and 56 is sequentially increased in proportion to the thickness of the source layers in transparent material layer 40. Each of the first to third quantum dots 52, 54, and 56 may absorb visible light of peak wavelength corresponding to the average diameter thereof, and transmit the other visible light of long wavelength. As the particle size of the first to third quantum dots 52, 54, and 56 is decreased, the wavelength of absorbed visible light may be decreased. On the contrary, as the particle size of the first to third quantum dots 52, 54, and 56 is increased, the wavelength of transmitted visible light may be increased.

The transparent material layer 40 containing quantum dots may be fabricated by coating precursor solutions containing quantum dots and post-annealing process.

For example, the first quantum dots 52 may absorb a blue spectrum having a wavelength ranging from about 400 nm to about 470 nm. In this case, the first quantum dots 52 may have a particle size of several nm. The first quantum dots 52 may transmit yellow or orange visible light, which is a mixture of green and red spectrums having a wavelength ranging from about 480 nm to about 700 nm. The second quantum dots 54 may absorb a blue to green spectrum having a wavelength ranging from about 400 nm to about 540 nm. As described above, the second quantum dots 54 may be greater in particle size than the first quantum dots 52. The second quantum dots 54 may transmit visible light, which is a mixture of yellow, orange, and red spectrums having a wavelength ranging from about 550 nm to about 700 nm. The third quantum dots 56 may absorb a blue to orange spectrum having a wavelength ranging from about 400 nm to about 670 nm. The third quantum dots 56 may transmit a red spectrum having a wavelength ranging from about 680 nm to about 700 nm. Thus, the first to third quantum dots 52, 54, and 56 may absorb visible light of peak wavelength proportional to particle size, to generate electricity, and may transmit the rest visible light of long wavelength to express colors.

As a result, the transparent color solar cell according to the current embodiment can maximize the photovoltaic efficiency and transparency thereof.

According to an embodiment of the present invention as described above, a transparent inorganic material layer including quantum dots having the same particle size may be disposed between a first electrode layer and a second transparent electrode. The quantum dots may absorb visible light of peak wavelength proportional to particle size, to generate electricity, and may transmit visible light of the other wavelength to express a color. The colors of light passing through the quantum dots may be varied according to particle sizes of the quantum dots.

Thus, a transparent color solar cell according to an embodiment of the present invention can maximize the photovoltaic efficiency and transparency thereof.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A transparent color solar cell comprising:
a substrate;
a first electrode layer disposed on the substrate;
a transparent material layer comprising quantum dots having the same particle size, which absorb visible light provided from the sun through the first electrode layer and having a first wavelength, and which selectively transmit visible light provided from the sun through the first electrode layer and having a second wavelength; and
a second electrode layer disposed on the transparent material layer.

2. The transparent color solar cell of claim 1, wherein the quantum dots comprise crystalline silicon or amorphous silicon.

3. The transparent color solar cell of claim 2, wherein the quantum dot comprising the crystalline silicon or the amorphous silicon has a diameter ranging from about 1 nm to about 100 nm.

4. The transparent color solar cell of claim 1, wherein the quantum dots comprise at least one of silicon germanium (SiGe), copper indium disulfide (CuInS₂), copper indium gallium diselenide (CuInGaSe₂), cadmium telluride (CdTe), and gallium arsenide (GaAs).

5. The transparent color solar cell of claim 1, wherein the transparent material layer comprises an inorganic dielectric material.

6. The transparent color solar cell of claim 5, wherein the inorganic dielectric material comprises at least one of a silicon oxide layer, a silicon nitride layer, and a silicon carbide layer.

7. The transparent color solar cell of claim 6, wherein the inorganic dielectric further comprises at least one of an aluminum oxide layer, a titanium oxide layer, a vanadium oxide layer, a tantalum oxide layer, and a zirconium oxide layer.

8. The transparent color solar cell of claim 1, further comprising:
a first impurity-added layer disposed between the first electrode layer and the transparent material layer; and
a second impurity-added layer disposed between the transparent material layer and the second electrode layer.

9. The transparent color solar cell of claim 8, wherein the first impurity-added layer comprises p-type semiconductor layer; and the second impurity-added layer comprises n-type semiconductor layer.
